(19) United States
(12) Patent Application Publication
(10) Pub. No.: US 2023/0284448 A1
(43) Pub. Date: Sep. 7, 2023

(54) THREE DIMENSIONAL FLASH MEMORY FOR IMPROVING LEAKAGE CURRENT

(71) Applicant: (IUCF-HYU (INDUSTRY-UNIVERSITY COOPERATION FOUNDATION HANYANG UNIVERSITY), Seoul (KR)

(72) Inventors: Yun Heub SONG, Seoul (KR); Bongseok KIM, Seoul (KR); Jaemin SIM, Seoul (KR); Sun Jun CHOI, Seoul (KR)

(73) Assignee: (IUCF-HYU (INDUSTRY-UNIVERSITY COOPERATION FOUNDATION HANYANG UNIVERSITY), Seoul (KR)

(21) Appl. No.: 18/008,306

(22) PCT Filed: May 4, 2021
(86) PCT No.: PCT/KR2021/005621

§ 371 Date: Dec. 5, 2022

(30) Foreign Application Priority Data
Jun. 5, 2020 (KR) 10-2020-0068008
Sep. 21, 2020 (KR) 10-2020-0121278
Oct. 19, 2020 (KR) 10-2020-0135313

(51) Int. Cl. H10B 43/27; H10B 43/40; H01L 21/02

(52) U.S. Cl. CPC H10B 43/27; H10B 43/40; H01L 21/02565

(57) ABSTRACT

A three-dimensional flash memory for improving leakage current and a substrate are disclosed. The three-dimensional flash memory comprises: a string extending in one direction on the substrate, wherein the string includes a channel layer extending in the one direction and a charge storage layer extending in the one direction so as to surround the channel layer; at least one selection line vertically connected to an upper end or a lower end of the string; and a plurality of word lines positioned above or below the at least one selection line and vertically connected to the string, wherein the channel layer is formed of an oxide semiconductor material.

### TECHNICAL FIELD

Embodiments below relate to a three-dimensional flash memory, and more particularly, relate to a three-dimensional flash memory capable of improving a leakage current.

### BACKGROUND ART

A flash memory device that is an electrically erasable programmable read only memory (EEPROM) may be used in common, for example, in a computer, a digital camera, an MP3 player, a game system, a memory stick, etc. The flash memory device electrically programs/erases data by using the F-N (Fowler-Nordheim) tunneling or the hot electron injection.

In detail, referring to FIG. 1 showing an array of a conventional three-dimensional flash memory, the array of the three-dimensional flash memory may include a common source line CSL, a bit line BL, and a plurality of cell strings CSTR interposed between the common source line CSL and the bit line BL.

Bit lines are arranged two-dimensionally, and the plurality of cell strings CSTR are connected in parallel with each of the bit lines. The cell strings CSTR may be connected in common with the common source line CSL. That is, the plurality of cell strings CSTR may be disposed between a plurality of bit lines and one common source line CSL. In this case, the common source line CSL may include a plurality of common source lines, and the plurality of common source lines CSL may be two-dimensionally arranged. Herein, the same voltage may be electrically applied to the plurality of common source lines CSL, or the plurality of common source lines CSL may be electrically controlled independently of each other.

Each of the cell strings CSTR may include a ground selection transistor GST connected with the common source line CSL, a string selection transistor SST connected with the bit line BL, and a plurality of memory cell transistors MCT interposed between the ground selection transistor GST and the string selection transistor SST. The ground selection transistor GST, the string selection transistor SST, and the memory cell transistors MCT may be connected in series.

The common source line CSL may be connected in common with sources of the ground selection transistors GST. In addition, a ground selection line GSL, a plurality of word lines WL0 to WL3, and a plurality of string selection lines SSL, which are disposed between the common source line CSL and the bit line BL, may be respectively used as electrode layers of the ground selection transistors GST, the memory cell transistors MCT, and the string selection transistors SST. Also, each of the memory cell transistors MCT includes a memory element. Below, the string selection line SSL may be expressed as an upper selection line USL, and the ground selection line GSL may be expressed as a lower selection line LSL.

Meanwhile, to satisfy requirements of a consumer such as excellent performance and low price, a conventional three-dimensional flash memory may increase the degree of integration by vertically stacking cells.

For example, referring to FIG. 2 showing a structure of a conventional three-dimensional flash memory, the conventional three-dimensional flash memory is manufactured by disposing electrode structures 215 in which interlayer insulating layers 211 and horizontal structures 250 are formed alternately and repeatedly on a substrate 200. The interlayer insulating layers 211 and the horizontal structures 250 may be extended in a first direction. The interlayer insulating layers 211 may be, for example, a silicon oxide layer, and the lowest interlayer insulating layer 211a among the interlayer insulating layers 211 may be smaller in thickness than the remaining interlayer insulating layers 211. Each of the horizontal structures 250 may include a first blocking insulating layer 242, a second blocking insulating layer 243, and an electrode layer 245. The conventional three-dimensional flash memory may include the plurality of electrode structures 215, and the plurality of electrode structures 215 may be disposed to face each other in a second direction intersecting the first direction. The first direction and the second direction may correspond to an x-axis and a y-axis of FIG. 2, respectively. Trenches 240 may be extended in the first direction such that the plurality of electrode structures 215 are spaced from each other. Impurity regions doped with impurities of a high concentration may be formed in the substrate 200 exposed by the trenches 240 such that the common source line CSL is disposed. Although not illustrated, device isolation layers filling the trenches 240 may be further disposed.

Vertical structures 230 penetrating the electrode structures 215 may be disposed. For example, in a plan view, the vertical structures 230 may be aligned along the first and second directions so as to be disposed in a matrix form. For another example, the vertical structures 230 may be aligned in the second direction and may be arranged in the first direction in a zig-zag form. Each of the vertical structures 230 may include a protection layer 224, a charge storage layer 225, a tunnel insulating layer 226, and a channel layer 227. For example, the channel layer 227 may be formed in the form of a hallow tube; in this case, a buried layer 228 filling the inside of the channel layer 227 may be further disposed. A drain region “D” may be disposed over the channel layer 227, and a conductive pattern 229 may be formed on the drain region “D” so as to be connected with a bit line BL. The bit line BL may be extended in a direction intersecting the horizontal structure 250, for example, the second direction. For example, the vertical structures 230 aligned in the second direction may be connected with one bit line BL.

The first and second blocking insulating layers 242 and 243 included in the horizontal structure 250 and the charge storage layer 225 and the tunnel insulating layer 226 included in the vertical structure 230 may be defined as an oxide-nitride-oxide (ONO) layer being an information storage element. That is, a portion of the information storage element may be included in the vertical structure 230, and the remaining portion thereof may be included in the horizontal structure 250. For example, the charge storage layer 225 and the tunnel insulating layer 226 of the information storage element may be included in the vertical structure 230, and the first and second blocking insulating layers 242 and 243 may be included in the horizontal structure 250.

Epitaxial patterns 222 may be disposed between the substrate 200 and the vertical structures 230. The epitaxial patterns 222 connect the substrate 200 and the vertical structures 230. The epitaxial patterns 222 may be in contact with the horizontal structures 250 in at least one layer. That is, the epitaxial patterns 222 may be disposed to be in contact with the lowest horizontal structure 250a. According to another embodiment, the epitaxial patterns 222 may be disposed to be in contact with the horizontal structures 250 in a plurality of layers, for example, two layers. Meanwhile, in the case where the epitaxial patterns 222 are disposed to be in contact with the lowest horizontal structure 250a, the lowest horizontal structure 250a may be greater in thickness than the remaining horizontal structures 250. The lowest horizontal structure 250a being in contact with the epitaxial patterns 222 may correspond to the ground selection line GSL of the array in the three-dimensional flash memory described with reference to FIG. 1, and the remaining horizontal structures 250 being in contact with the vertical structures 230 may correspond to the plurality of word lines WL0 to WL3, respectively.

Each of the epitaxial patterns 222 includes a recessed side wall 222a. As such, the lowest horizontal structure 250a being in contact with the epitaxial patterns 222 is disposed along a profile of the recessed side wall 222a. That is, the lowest horizontal structure 250a may be disposed to be convex inwardly along the recessed side wall 222a of the epitaxial pattern 222.

Because the channel layer 227 is formed of poly-silicon, the conventional three-dimensional flash memory with the above structure is problematic in that a leakage current is great. As such, to suppress the leakage current, a structure in which the number of string selection lines SSL is increased has been provided.

However, the structure in which the number of string selection lines SSL is increased causes a disadvantage of adversely affecting the degree of integration of a memory.

Accordingly, the following embodiments are directed to provide a technique for improving a leakage current characteristic in a three-dimensional flash memory and promoting memory integration and miniaturization.

Also, referring to FIG. 3 illustrating an X-Z cross-sectional view of a conventional three-dimensional flash memory, a three-dimensional flash memory 300 includes a plurality of word lines 310 that are extended and formed in a horizontal direction on a substrate 305 and are sequentially stacked, a ground selection line (GSL) 320 that is located under the plurality of word lines 310, and at least one string 330 that are extended and formed in a direction perpendicular to the substrate 305 so as to penetrate the plurality of word lines 310 and the GSL 320 (the at least one string 330 is composed of a channel layer 331 extended and formed in a vertical direction and a charge storage layer 332 surrounding the channel layer).

In the three-dimensional flash memory 300 with the above structure, a leakage current may occur in the GSL 320. A conventional three-dimensional flash memory has solved the above issue by applying a structure (more precisely, a structure in which a nitride layer of the ONO layer being the charge storage layer 332 is not disposed at a location corresponding to the GSL 320) in which the charge storage layer 332 is not disposed at a location corresponding to the GSL 320 and a structure (the remaining region of the channel layer 331 being formed of poly-silicon) in which both the entire substrate 305 and a region 331-1 of the channel layer 331, which corresponds to the GSL 320, are formed of poly-silicon.

However, in the case where a COP (Cell On Peri.) structure is applied to the conventional three-dimensional flash memory to improve the degree of integration, because it is impossible to form the entire substrate 305 with poly-silicon, it is also impossible to form the region 331-1 of the channel layer 331, which corresponds to the GSL 320, with poly-silicon. As such, a technique for improving and preventing a leakage current at the GSL of the three-dimensional flash memory to which the COP structure is applied is required.

Also, referring to FIG. 4 illustrating an X-Z cross-sectional view of a conventional three-dimensional flash memory to which a conventional COP structure is applied, in the case where the COP (Cell On Peri.) structure is applied to a conventional three-dimensional flash memory 400 to improve the degree of integration, because it is impossible to form the entire substrate 305 with poly-silicon, it is also impossible to form a region 411 of a channel layer 410, which corresponds to a GSL 420, with poly-silicon (the region 411 being also formed of poly-silicon). As such, a technique for improving and preventing a leakage current at the GSL of the three-dimensional flash memory to which the COP structure is applied is required.

### DETAILED DESCRIPTION OF THE INVENTION

### Technical Problem

Embodiments provide a three-dimensional flash memory that improves a leakage current characteristic and also promotes memory integration and miniaturization.

In detail, some embodiments provide a three-dimensional flash memory that includes a channel layer formed of an oxide semiconductor material to have an excellent leakage current characteristic of the oxide semiconductor material and also promotes memory integration and miniaturization by changing a physical structure of at least one selection line having an excellent leakage current characteristic of the oxide semiconductor material.

Embodiments propose a three-dimensional flash memory that improves a leakage current of a GSL in a COP structure.

In detail, embodiments provide a three-dimensional flash memory that improves a leakage current characteristic of a GSL transistor (TR) by forming a region of a channel layer, which corresponds to the GSL, with silicon.

Embodiments provide a substrate having a structure for forming a region of a channel layer, which corresponds to a GSL, with single crystal silicon to improve a leakage current of the GSL in a three-dimensional flash memory to which a COP structure is applied.

In detail, embodiments provide a substrate having a structure in which the region of the channel layer corresponding to the GSL is formed of single crystal silicon through epitaxial growth and that also allows a peripheral circuit by the COP structure to be embedded.

### Technical Solution

According to an embodiment, a three-dimensional flash memory includes a string extended and formed in one direction on a substrate, the string including a channel layer extended and formed in the one direction and a charge storage layer extended and formed in the one direction to surround the channel layer, at least one selection line vertically connected with an upper end or a lower end of the string, and a plurality of word lines located over or under the at least one selection line and vertically connected with the string, and the channel layer is formed of an oxide semiconductor material.

According to an aspect, the entire channel layer may be formed of the oxide semiconductor material.

According to another aspect, a physical structure of the at least one selection line may be determined based on a leakage current characteristic of the oxide semiconductor material forming the channel layer.

According to another aspect, the number or thickness of the at least one selection line may be adjusted based on the leakage current characteristic of the oxide semiconductor material forming the channel layer.

According to another aspect, the at least one selection line may be formed to be thinner than a thickness of each of the plurality of word lines.

According to an embodiment, a three-dimensional flash memory to which a COP structure is applied includes a plurality of word lines extended formed in a horizontal direction on a substrate and sequentially stacked, a ground selection line (GSL) located under the plurality of word lines, and at least one string extended and formed in a vertical direction on the substrate to penetrate the plurality of word lines and the GSL, the at least one string includes a channel layer extended and formed in the vertical direction and a charge storage layer extended and formed in the vertical direction to surround the channel layer, and a partial region of the channel layer, which corresponds to the GSL, is formed of silicon by using crystallized silicon of an upper surface of the substrate.

According to an aspect, the partial region of the channel layer, which corresponds to the GSL, may be formed of the silicon through epitaxial growth that is based on the crystallized silicon of the upper surface of the substrate.

According to another aspect, the upper surface of the substrate may be crystallized to the silicon as a laser annealing technique is applied to poly-silicon forming the substrate.

According to another aspect, a remaining region of the channel layer, which corresponds to the plurality of word lines, may be formed of poly-silicon.

According to another aspect, a remaining region of the substrate other than the upper surface may be formed of poly-silicon.

According to an embodiment, a substrate to which a COP structure used in a three-dimensional flash memory is applied includes an epitaxial seed region used for epitaxial growth for forming a portion of a channel layer included in the three-dimensional flash memory with single crystal silicon, the portion of the channel layer corresponding to a ground selection line (GSL), and a peripheral circuit region in which a peripheral circuit is embedded by the COP structure.

According to an aspect, the epitaxial seed region and the peripheral circuit region may form a pattern in which the epitaxial seed region and the peripheral circuit region are disposed alternately and repeatedly on the substrate.

According to another aspect, an epitaxial growth layer in which single crystal silicon formed through the epitaxial growth from the epitaxial seed region may be smoothed is disposed on an upper portion of the epitaxial seed region and the peripheral circuit region.

According to another aspect, the substrate may further include a poly-silicon layer disposed on the epitaxial growth layer.

According to another aspect, the poly-silicon layer may include at least one vertical hole filled with the single crystal silicon formed through the epitaxial growth from the epitaxial seed region.

### Advantageous Effects of the Invention

Embodiments may provide a three-dimensional flash memory that improves a leakage current characteristic and also promotes memory integration and miniaturization.

In detail, embodiments may provide a three-dimensional flash memory that includes a channel layer formed of an oxide semiconductor material to have an excellent leakage current characteristic of the oxide semiconductor material and also promotes memory integration and miniaturization by changing a physical structure of at least one selection line having an excellent leakage current characteristic of the oxide semiconductor material.

Embodiments may provide a three-dimensional flash memory that improves a leakage current of a GSL in a COP structure.

In detail, embodiments may provide a three-dimensional flash memory that improves a leakage current characteristic of a GSL transistor (TR) by forming a region of a channel layer, which corresponds to the GSL, with silicon.

Accordingly, a leakage current at the GSL may be prevented and improved while improving the degree of integration.

Embodiments may improve the degree of integration of a memory and may also improve a leakage current of the GSL, by providing a substrate having a structure for forming a region of a channel layer, which corresponds to the GSL, with single crystal silicon in a three-dimensional flash memory to which a COP structure is applied.

In detail, embodiments may provide a substrate having a structure in which the region of the channel layer corresponding to the GSL is formed of single crystal silicon through epitaxial growth and that also allows a peripheral circuit by the COP structure to be embedded.

### DESCRIPTION OF THE DRAWINGS

FIG. 1 is a circuit diagram illustrating an array of a conventional three-dimensional flash memory.

FIG. 2 is a perspective view illustrating a structure of a conventional three-dimensional flash memory.

FIG. 3 is an X-Z cross-sectional view illustrating a conventional three-dimensional flash memory.

FIG. 4 is an X-Z cross-sectional view illustrating a three-dimensional flash memory to which a conventional COP structure is applied.

FIG. 5 is a diagram for describing a leakage current characteristic of an oxide semiconductor material.

FIG. 6 is a Y-Z cross-sectional view illustrating a three-dimensional flash memory according to an embodiment.

FIG. 7 is a Y-Z cross-sectional view illustrating a three-dimensional flash memory according to another embodiment.

FIG. 8 is a flowchart illustrating a three-dimensional flash memory manufacturing method according to an embodiment.

FIGS. 9A to 9D are Y-Z cross-sectional views for describing a three-dimensional flash memory manufacturing method according to an embodiment.

FIG. 10 is an X-Z cross-sectional view illustrating a three-dimensional flash memory according to embodiment.

FIG. 11 is a flowchart illustrating a three-dimensional flash memory manufacturing method according to an embodiment.

FIGS. 12 to 15 are X-Z cross-sectional views for describing a three-dimensional flash memory manufacturing method according to an embodiment.

FIG. 16 is an X-Z cross-sectional view illustrating a substrate to which a COP structure used in a three-dimensional flash memory according to an embodiment is applied.

FIG. 17 is an X-Z cross-sectional view illustrating a three-dimensional flash memory in which a substrate illustrated in FIG. 16 is used.

FIG. 18 is a flowchart illustrating a method for manufacturing a three-dimensional flash memory using a substrate to which a COP structure according to an embodiment is applied.

FIGS. 19A to 19E are X-Z cross-sectional views illustrating a three-dimensional flash memory for describing a manufacturing method illustrated in FIG. 18.

FIG. 20 is an X-Z cross-sectional view illustrating a substrate to which a COP structure used in a three-dimensional flash memory according to another embodiment is applied.

FIG. 21 is an X-Z cross-sectional view illustrating a three-dimensional flash memory in which a substrate illustrated in FIG. 20 is used.

FIG. 22 is a flowchart illustrating a method for manufacturing a three-dimensional flash memory using a substrate to which a COP structure according to another embodiment is applied.

FIGS. 23A to 23F are X-Z cross-sectional views illustrating a three-dimensional flash memory for describing a manufacturing method illustrated in FIG. 22.

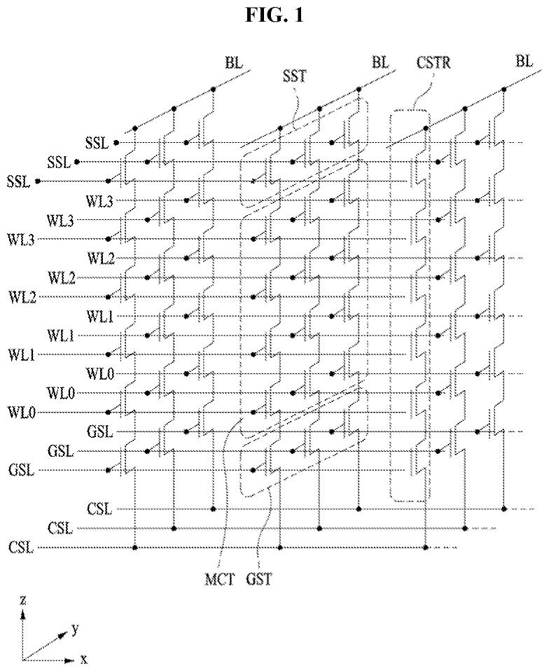

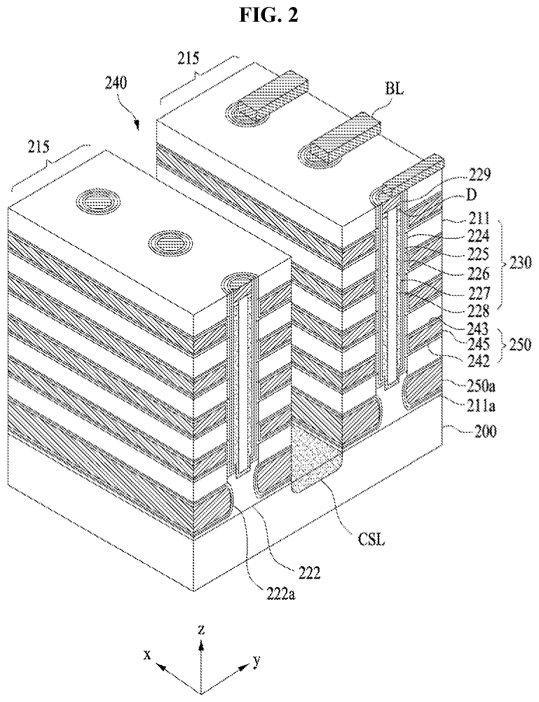

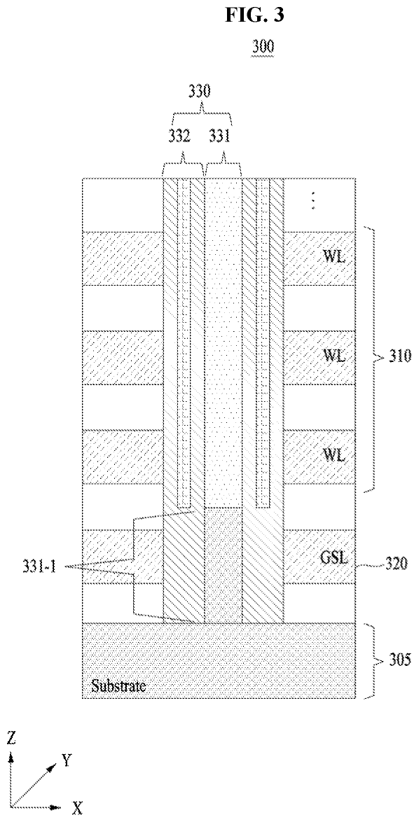

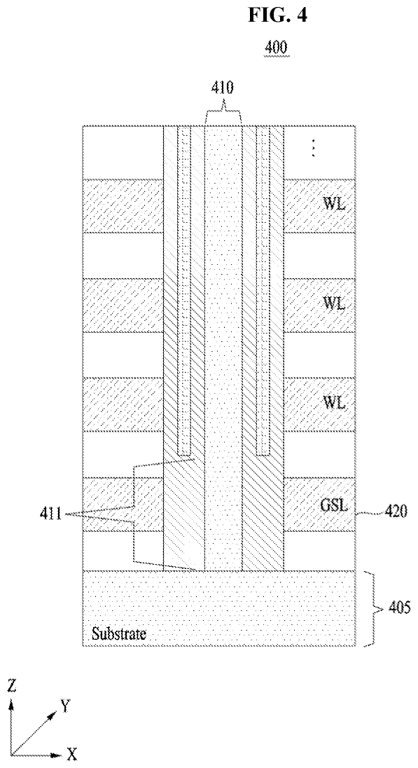

### BEST MODE

Hereinafter, embodiments will be described in detail with reference to the accompanying drawings. However, the present disclosure are not limited or restricted by the embodiments. Further, the same reference signs/numerals in the drawings denote the same members.

Furthermore, the terminologies used herein are used to properly express the embodiments of the present disclosure, and may be changed according to the intentions of the user or the manager or the custom in the field to which the invention pertains. Accordingly, definition of the terms should be made according to the overall disclosure set forth herein.

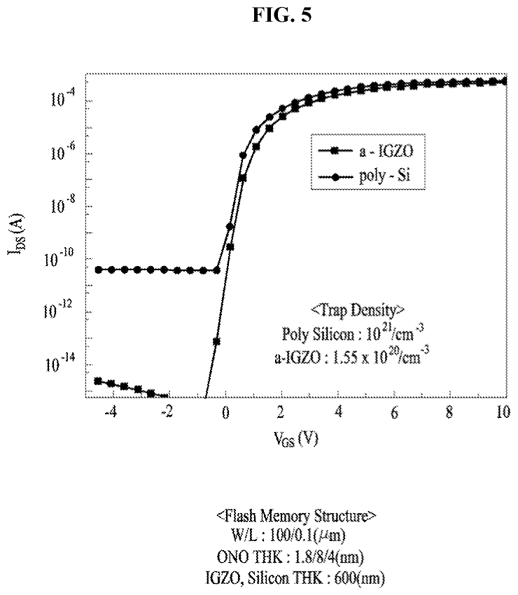

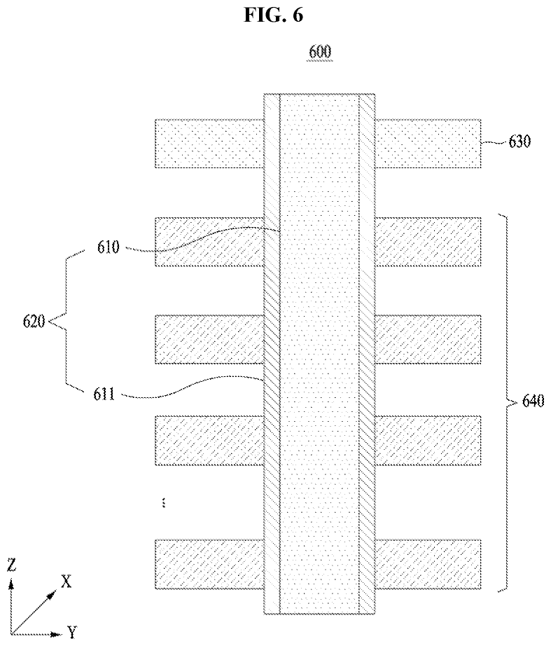

FIG. 5 is a diagram for describing a leakage current characteristic of an oxide semiconductor material, and FIG. 6 is a Y-Z cross-sectional view illustrating a three-dimensional flash memory according to an embodiment.

The oxide semiconductor material that includes a material (e.g., a ZnOx-based material including AZO, ZTO, IZO, ITO, IGZO, or Ag—ZnO) containing at least one of In, Zn, or Ga or an oxide containing a Group 4 semiconductor material has a characteristic that a leakage current level of the oxide semiconductor material is markedly low compared to poly-silicon, as shown by a graph of FIG. 5.

Accordingly, a three-dimensional flash memory 600 according to an embodiment described with reference to FIG. 6 is characterized in that there is included a channel layer 610 based on the oxide semiconductor material having an excellent leakage current characteristic compared to poly-silicon.

In detail, the three-dimensional flash memory 600 may include a string 620 including the channel layer 610 and a charge storage layer 611, at least one selection line 630, and a plurality of word lines 640. Below, for convenience of description, the three-dimensional flash memory 600 that essentially includes the string 620, the at least one selection line 630, and the plurality of word lines 640 is illustrated, but a plurality of insulating layers (not illustrated) interposed between the plurality of word lines 640, a bit line disposed over the string 620, and a source line disposed under the string 620 are omitted. Also, below, the description will be given based on a drawing where the three-dimensional flash memory 600 includes one string 620, but the present disclosure is not limited thereto. For example, the three-dimensional flash memory 600 may include a plurality of strings. In this case, a structure of one string to be described later may be applied to each of the plurality of strings without modification.

The string 620 may be extended and formed in one direction (e.g., a z-direction) on a substrate and may include the channel layer 610 and the charge storage layer 611 to constitute memory cells respectively corresponding to the plurality of word lines 640 connected in a vertical direction.

The charge storage layer 611 that is a component where charges are stored by voltages applied through the plurality of word lines 640 in a state of being extended and formed to surround the channel layer 610 may act as data storage of the three-dimensional flash memory 600; as an example, the charge storage layer 611 may be formed in an oxide-nitride-oxide (ONO) structure or may be formed of a ferroelectric layer such as HfOx.

The channel layer 610 may be formed of an oxide semiconductor material, and a buried layer (not illustrated) filling the inside thereof may be further included. In particular, as not a portion of the channel layer 610 but the entire channel layer 610 is formed of an oxide semiconductor material having an excellent leakage current characteristic, it may be possible to block and suppress a leakage current through the entire region of the channel layer 610. Below, that a leakage current characteristic of an oxide semiconductor material is excellent means that the oxide semiconductor material has a leakage current of a small value compared to a leakage current characteristic of poly-silicon being a material forming a conventional channel layer.

Herein, the oxide semiconductor material may include a material (e.g., a ZnOx-based material including AZO, ZTO, IZO, ITO, IGZO, or Ag—ZnO) containing at least one of In, Zn, or Ga having an excellent leakage current characteristic or a Group 4 semiconductor material.

The at least one selection line 630 that is one of at least one string selection line SSL connected vertically with an upper end of the string 620 (at least one string selection line being connected with a bit line (not illustrated) located over the string 620) or at least one ground selection line GSL connected vertically with a lower end of the string 620 (at least one ground selection line being connected with a source line (not illustrated) located under the string 620) may be formed of a conductive material such as tungsten (W), titanium (Ti), tantalum (Ta), copper (Cu), or gold (Au). Below, the at least one selection line 630 is illustrated in drawing as one string selection line but is not limited thereto as described.

In particular, a physical structure of the at least one selection line 630 may be determined based on a leakage current characteristic of the oxide semiconductor material forming the channel layer 610. For example, the number of at least one selection line 630 may be adjusted based on an excellent leakage current characteristic of the oxide semiconductor material forming the channel layer 610. In detail, because the three-dimensional flash memory 600 has an excellent leakage current characteristic of the oxide semiconductor material forming the channel layer 610, as illustrated in drawing, the three-dimensional flash memory 600 may include one string selection line and one ground selection line for each string 620.

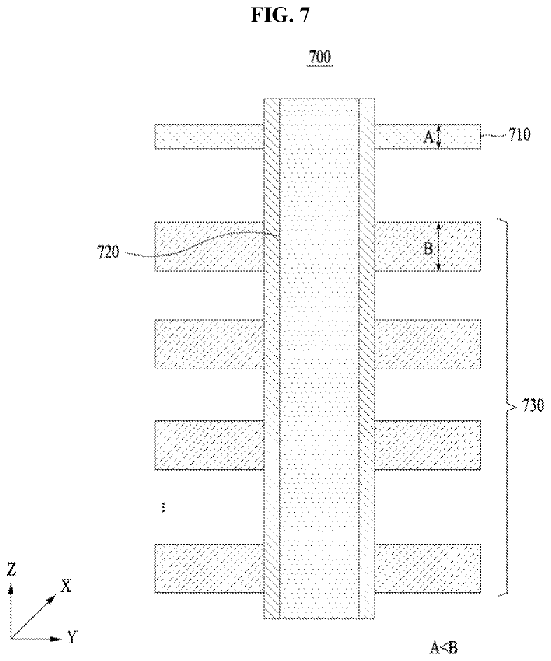

For another example, a thickness of the at least one selection line 630 may be adjusted based on a leakage current characteristic of the oxide semiconductor material forming the channel layer 610. This will be described in detail with reference to FIG. 7.

The plurality of word lines 640 may be located above or below the at least one selection line 630, may be vertically connected with the string 620, may be formed of a conductive material such as tungsten (W), titanium (Ti), tantalum (Ta), copper (Cu), or gold (Au), and a memory operation (e.g., a read operation, a program operation, and an erase operation) may be performed by applying voltages to memory cells corresponding to the plurality of word lines 640.

FIG. 7 is a Y-Z cross-sectional view illustrating a three-dimensional flash memory according to another embodiment.

Referring to FIG. 7, at least one selection line 710 of a three-dimensional flash memory 700 according to another embodiment is different in structure from that of the three-dimensional flash memory 600 described with reference to FIG. 6, and the remaining components of the three-dimensional flash memory 700 are identical in structure to those of the three-dimensional flash memory 600; therefore, below, the at least one selection line 710 and a channel layer 720 vertically connected with the at least one selection line 710 will be described only.

The three-dimensional flash memory 700 according to another embodiment is characterized in that a thickness being a physical structure of the at least one selection line 710 is adjusted by forming the channel layer 720 with an oxide semiconductor material whose leakage current characteristic is excellent. In detail, the thickness of the at least one selection line 710 may be adjusted based on a leakage current characteristic of the oxide semiconductor material forming the channel layer 720, for example, may be adjusted and determined to be thinner than a thickness of each of a plurality of word lines 730. However, the present disclosure is not limited thereto. The at least one selection line 710 may be formed to have a thin thickness compared to a selection line of a conventional three-dimensional flash memory having a poly-silicon-based channel layer.

As described above, the three-dimensional flash memory 600/700 may have an excellent leakage current characteristic by forming the channel layer 610/720 with an oxide semiconductor material, and the memory integration and miniaturization may be promoted by changing the physical structure of the at least one selection line 630/710 thanks to the excellent leakage current characteristic of the oxide semiconductor material. The description is given above as the change in the physical structure of the at least one selection line 630/710 corresponds to a change of one of the number of lines or the thickness, but the present disclosure is not limited to the change of one of the number of lines or the thickness. Both the number of lines and the thickness may be changed.

Also, as the three-dimensional flash memory 600/700 includes the channel layer 610/720 formed of the oxide semiconductor material, the three-dimensional flash memory 600/700 may have the excellent leakage current characteristic and may also make it possible to improve a transistor characteristic (e.g., a threshold voltage distribution of string cells and a speed of a program/read operation) of the at least one selection line 630/710.

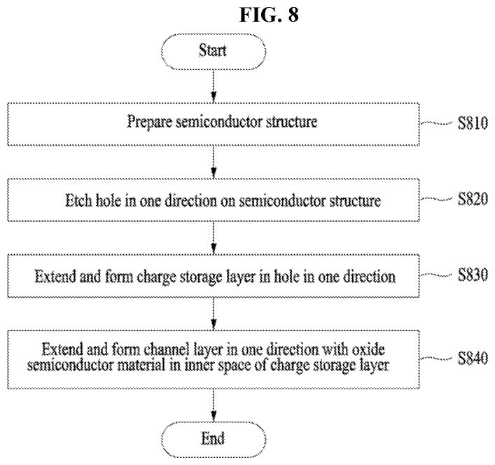

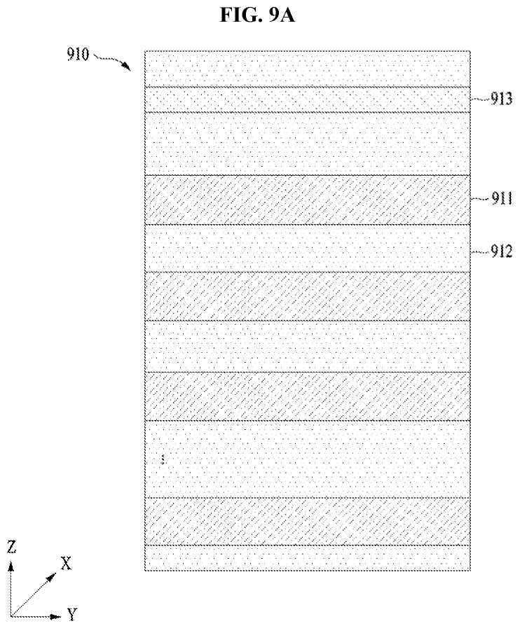

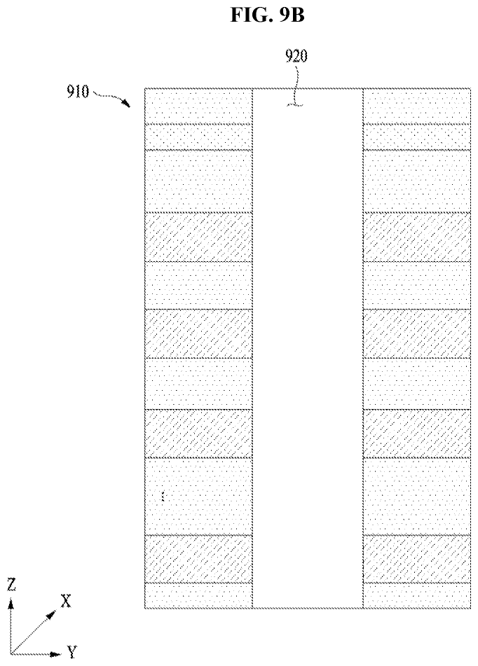

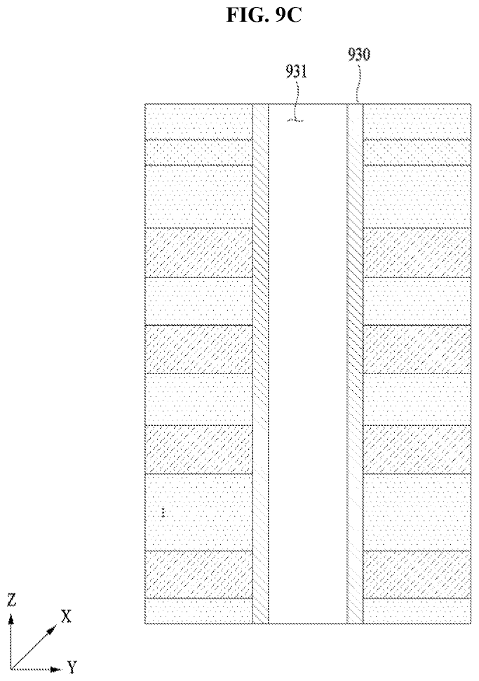

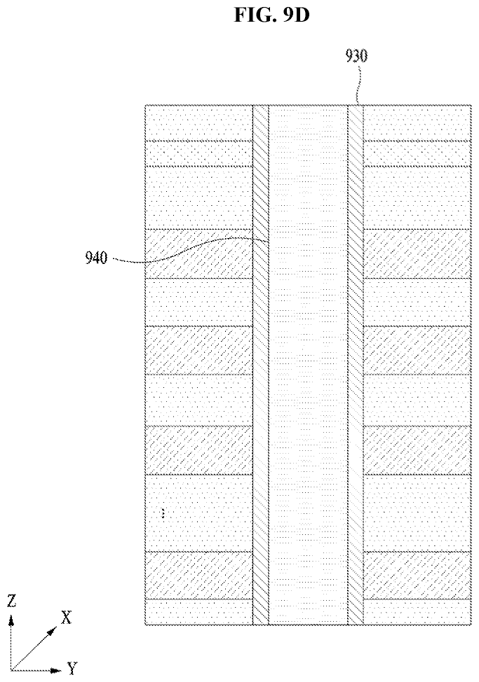

FIG. 8 is a flowchart illustrating a three-dimensional flash memory manufacturing method according to an embodiment, and FIGS. 9A to 9D are Y-Z cross-sectional views for describing the three-dimensional flash memory manufacturing method according to an embodiment. The description will be given under the condition that a three-dimensional flash memory manufacturing method to be described below is performed by an automated and mechanized manufacturing system, and the three-dimensional flash memory manufacturing method means a method for manufacturing the three-dimensional flash memories 600 and 700 described with reference to FIGS. 6 and 7.

First, in step S810, the manufacturing system may prepare a semiconductor structure 910 in which a plurality of word lines 911 and a plurality of insulating layers 912 are alternately stacked and at least one selection line 913 is stacked on an upper portion or a lower portion thereof, as illustrated in FIG. 9A.

Herein, the at least one selection line 913 in the semiconductor structure 910 may be one of at least one string selection line (SSL) or at least one ground selection line (GSL) and may be formed of a conductive material such as tungsten (W), titanium (Ti), tantalum (Ta), copper (Cu), or gold (Au); the plurality of word lines 911 in the semiconductor structure 910 may also be formed of a conductive material such as tungsten (W), titanium (Ti), tantalum (Ta), copper (Cu), or gold (Au). In contrast, the plurality of insulating layers 912 in the semiconductor structure 910 may be formed of an insulating material.

Below, the case where the at least one selection line 913 is stacked on the upper portion of the semiconductor structure 910 is illustrated in drawings, but the present disclosure is not limited thereto. The three-dimensional flash memory may also be manufactured through step S810 to step S840 even in the case where the at least one selection line 913 is stacked on the lower portion of the semiconductor structure 910.

Next, in step S820, the manufacturing system may etch a hole 920 in one direction on the semiconductor structure 910 as illustrated in FIG. 9B. Herein, the hole 920 means a circular trench.

Afterwards, in step S830, the manufacturing system may form a charge storage layer 930 in the hole 920 so as to be extended and formed in one direction (e.g., a z-direction), as illustrated in FIG. 9C. For example, the manufacturing system may form the charge storage layer 930 on an inner wall of the hole 920 such that the charge storage layer 930 has an inner space 931.

Then, in step S840, the manufacturing system may form a channel layer 940 with an oxide semiconductor material so as to be extended and formed in one direction (e.g., a z-direction) in the inner space 931 of the charge storage layer 930, as illustrated in FIG. 9D. In detail, the manufacturing system may form the entire channel layer 940 with the oxide semiconductor material by filling the entire inner space 931 of the charge storage layer 930 with the oxide semiconductor material. Herein, the oxide semiconductor material may be a material containing at least one of In, Zn, or Ga or a material containing a Group 4 semiconductor material.

As described above, in step S840, because the channel layer 940 is formed of the oxide semiconductor material whose leakage current characteristic is excellent, the at least one selection line 913 in the semiconductor structure 910 prepared in step S810 may have a physical structure that is determined based on a leakage current characteristic of the oxide semiconductor material forming the channel layer 940. In detail, in step S810, the manufacturing system may prepare the semiconductor structure 910 that includes the at least one selection line 913, the number or thickness of which is adjusted based on the leakage current characteristic of the oxide semiconductor material forming the channel layer 940. For example, in step S810, the manufacturing system may prepare the semiconductor structure 910 including the at least one selection line 913 whose thickness is thinner than a thickness of each of the plurality of word lines 911 or may prepare the semiconductor structure 910 including the at least one selection line 913 implemented as one.

Below, in the X-Z cross-sectional view showing a three-dimensional flash memory, the three-dimensional flash memory will be illustrated and described under the assumption that components such as a bit line located on/over at least one string and a source line located under the at least one string are omitted for convenience of description. However, the three-dimensional flash memory to be described later is not limited thereto, and may be configured to include components necessary for a typical flash memory.

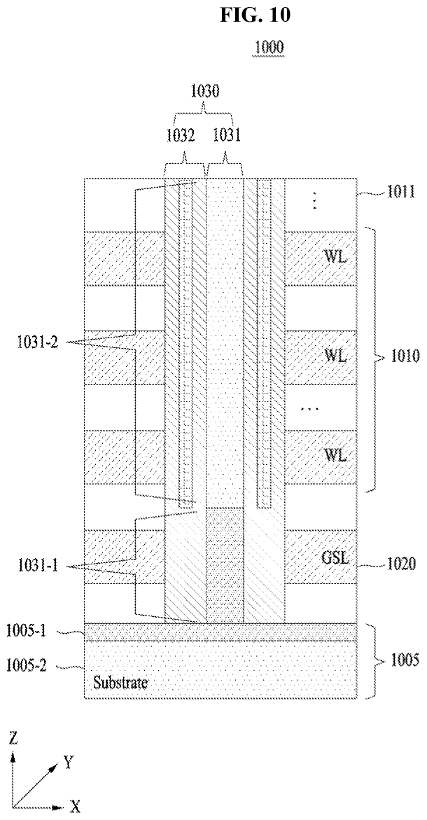

FIG. 10 is an X-Z cross-sectional view illustrating a three-dimensional flash memory according to embodiment.

Referring to FIG. 10, a three-dimensional flash memory 1000 according to an embodiment includes a plurality of word lines 1010, a GSL 1020 located under the plurality of word lines 1010, and at least one string 1030.

A substrate 1005 where the plurality of word lines 1010, the GSL 1020 located under the plurality of word lines 1010, and the at least one string 1030 may be formed of poly-silicon to apply the COP structure; however, an upper surface may be formed of silicon (hereinafter, the expression “silicon” meaning “single crystal silicon”) crystallized for a leakage current prevention structure of the GSL to be described later (the remaining region 1005-2 of the substrate 1005 other than an upper surface 1005-1 being formed of poly-silicon). Although not illustrated in drawing, below, as the COP structure is applied, the substrate 1005 may include at least one peripheral circuit.

The plurality of word lines 1010 may be sequentially stacked on the substrate 1005 in a state of being extended and formed in a horizontal direction (e.g., an x-direction), and each of the word lines 1010 may be formed of a conductive material, such as tungsten (W), titanium (Ti), tantalum (Ta), copper (Cu), molybdenum (Mo), ruthenium (Ru), or gold (Au), (in addition to the described conductive material, including all conductive materials capable of forming an ALD). A memory operation (e.g., a read operation, a program operation, or an erase operation) may be performed by applying voltages to memory cells respectively corresponding to the word lines 1010. A plurality of insulating layers 1011 that is formed of an insulating material may be interposed between the plurality of word lines 1010.

A string selection line SSL (not illustrated) may be disposed on/over the plurality word lines 1010, and a ground selection line (GSL) 1020 (e.g., the GSL being connected with a common source line CSL (not illustrated) may be disposed under the plurality of word lines 1010.

The at least one string 1030 may include a channel layer 1031 and a charge storage layer 1032, each of which is extended and formed in a vertical direction (e.g., a z-direction) on the substrate 1005 to penetrate the plurality of word lines 1010 and the GSL 1020.

The charge storage layer 1032 that is a component storing charges from a current introduced through the plurality of word lines 1010 in a state of being extended and formed in the vertical direction to surround the channel layer 1031 may be extended and formed at a location corresponding to the plurality of word lines 1010 (in detail, a nitride layer of the charge storage layer 1032 with the oxide-nitride-oxide (ONO) structure being extended and formed at a location corresponding to the plurality of word lines 1010 and the remaining oxide layers thereof being extended and formed to a location corresponding to the GSL 1020).

Herein, the description is given as the charge storage layer 1032 is formed in the ONO structure, but the present disclosure is not limited thereto. There may be used various charge storage components that maintain a state of charges by trapping charges or holes by voltages applied through the plurality of word lines 1010.

Also, the description is given as the charge storage layer 1032 includes only a vertical element extended and formed in a vertical direction (e.g., a z-direction) perpendicular to the substrate 1005, but the present disclosure is not limited thereto. A horizontal component that is parallel to the substrate 1005 and is in contact with the plurality word lines 1010 may be further included.

The channel layer 1031 that is a component for storing charges from a current introduced through the plurality of word lines 1010 in a state of being extended and formed in the vertical direction to surround the charge storage layer 1032 may be extended and formed from a location corresponding to the plurality of word lines 1010 to a location corresponding to the GSL 1020

In particular, in the three-dimensional flash memory 1000 according to an embodiment, a partial region 1031-1 of the channel layer 1031 (e.g., a partial region of the channel layer 1031, which correspond to the GSL 1020) may be formed of silicon (hereinafter, the expression “silicon” meaning “single crystal silicon”), and the remaining region 1031-2 (e.g., the remaining region of the channel layer 1031, which corresponds to the plurality of word lines 1010) may be formed of poly-silicon.

In this case, the partial region 1031-1 of the channel layer 1031, which corresponds to the GSL 1020, may be formed of silicon by using the crystallized silicon of the upper surface 1005-1 of the substrate 1005. For example, as a laser annealing technique is applied to poly-silicon forming the substrate 1005, the upper surface 1005-1 of the substrate 1005 may be crystallized to silicon. As such, the partial region 1031-1 of the channel layer 1031, which corresponds to the GSL 1020, may be formed of silicon through the epitaxial growth that is based on the crystallized silicon of the upper surface 1005-1 of the substrate 1005.

The technique and process that are applied to crystallize the upper surface 1005-1 of the substrate 1005 to silicon are not limited to the laser annealing technique described above, and various techniques or processes that crystallize poly-silicon to form silicon may be utilized.

As described above, as the partial region 1031-1 of the channel layer 1031 corresponding to the GSL 1020 is formed of silicon, the remaining region 1031-2 of the channel layer 1031 corresponding to the plurality of word lines 1010 is formed of poly-silicon, and the remaining region 1005-2 of the substrate 1005 other than the upper surface 1005-1 is also formed of poly-silicon, the three-dimensional flash memory 1000 according to an embodiment may improve the degree of integration by applying the COP structure and may prevent a leakage current at the GSL by improving a leakage current characteristic of the GSL TR (GSL TR referring to a region of the charge storage layer 1032, which is in contact with the GSL 1020) while guaranteeing a channel characteristic associated with the memory operation in the remaining region 1031-2 of the channel layer 1031 corresponding to the plurality of word lines 1010.

A method for manufacturing the three-dimensional flash memory 1000 described above will be described below.

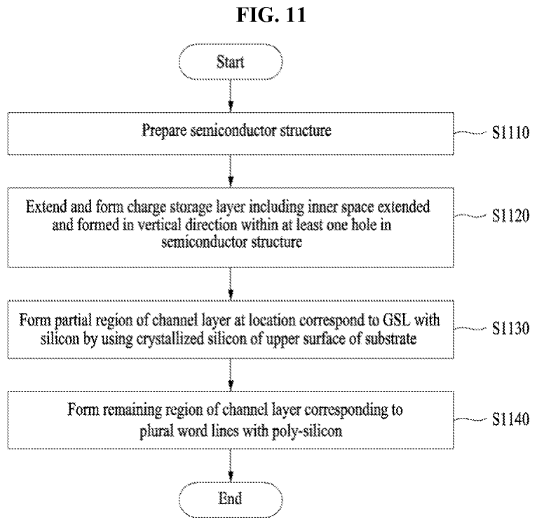

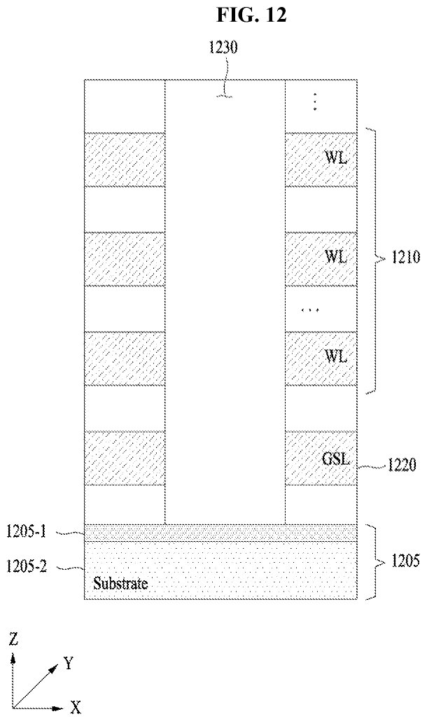

FIG. 11 is a flowchart illustrating a three-dimensional flash memory manufacturing method according to an embodiment, and FIGS. 12 to 15 are X-Z cross-sectional views for describing the three-dimensional flash memory manufacturing method according to an embodiment. A manufacturing method to be described below is for manufacturing the three-dimensional flash memory described with reference to FIG. 10 and may be performed by the automated and mechanized system.

Referring to FIGS. 11 to 15, in step S1110, the manufacturing system may prepare a semiconductor structure 1210 as illustrated in FIG. 12.

Herein, the semiconductor structure 1210 may include a plurality of word lines 1210 that are extended and formed in a horizontal direction on a substrate 1205 and are sequentially stacked, a ground selection line (GSL) 1220 located under the plurality of word lines 1210, and at least one hole 1230 that is extended and formed in the vertical direction on the substrate 1205 to penetrate the plurality of word lines 1210 and the GSL 1220.

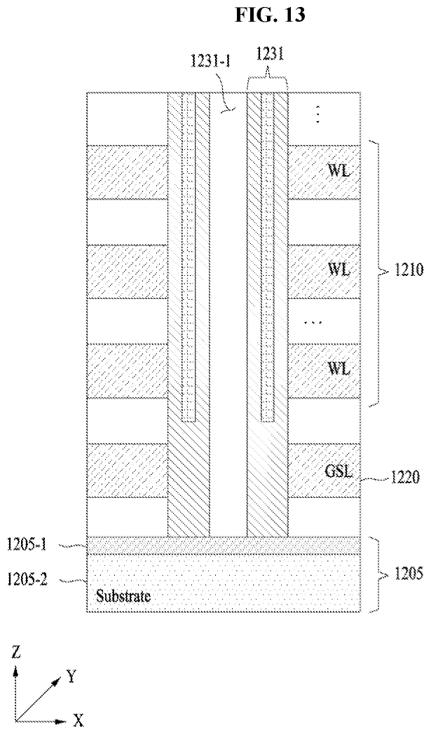

Next, in step S1120, the manufacturing system may extend and form a charge storage layer 1231 including an inner space 1231-1 extended and formed in a vertical direction within the at least one hole 1230 in the semiconductor structure 1210 as illustrated in FIG. 13.

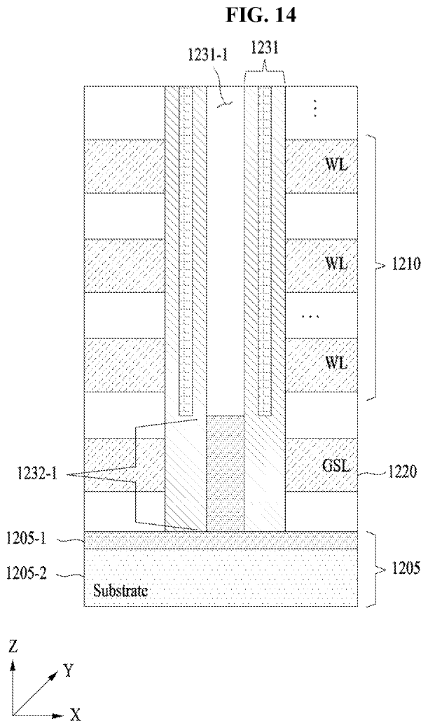

Afterwards, in step S1130, the manufacturing system may form a partial region 1232-1 of a channel layer 1232 at a location corresponding to the GSL 1220 by using the crystallized silicon of an upper surface 1205-1 of the substrate 1205, through the inner space 1231-1 of the charge storage layer 1231 as illustrated in FIG. 14.

In detail, in step S1130, the manufacturing system may form the partial region 1232-1 of the channel layer 1232 with silicon through the epitaxial growth that is based on the crystallized silicon of the upper surface 1205-1 of the substrate 1205.

In this case, the upper surface 1205-1 of the substrate 1205 may be crystallized to silicon by applying the laser annealing technique to poly-silicon forming the substrate 1205. As described above, to crystallize the upper surface 1205-1 of the substrate 1205 to silicon may be performed in the process of manufacturing the semiconductor structure 1210 before step S1110, but the present disclosure is not limited thereto. To crystallize the upper surface 1205-1 may be performed between step S1110 and step S1120. That is, although not illustrated in drawing, the manufacturing system may crystallize the upper surface 1205-1 of the substrate 1205 to silicon by applying the laser annealing technique to poly-silicon forming the substrate 1205 in the process of manufacturing the semiconductor structure 1210 before step S1110 or may crystallize the upper surface 1205-1 of the substrate 1205 to silicon by applying the laser annealing technique to poly-silicon forming the substrate 1205 after step S1110 and before step S1120.

When the upper surface 1205-1 of the substrate 1205 is crystallized to silicon between step S1110 and step S1120, the laser annealing technique may be performed through the at least one hole 1230 that is already formed in step S1110.

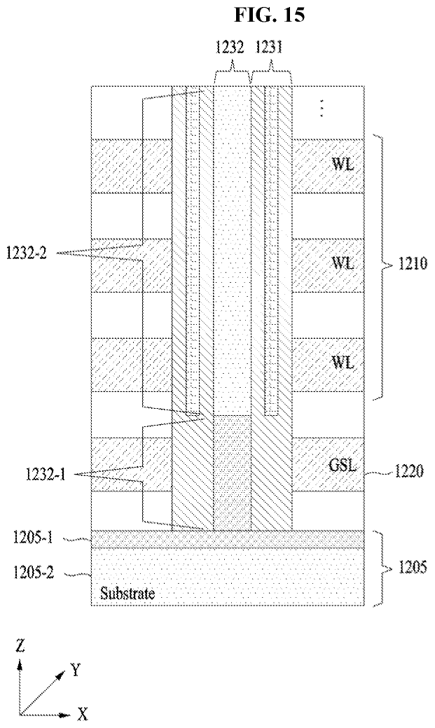

Afterwards, in step S1140, the manufacturing system may form the remaining region 1232-2 of the channel layer 1232, which corresponds to the plurality of word lines 1210, with poly-silicon as illustrated in FIG. 15. Then, the entire region of the channel layer 1232 may be formed as step S1140 is completed.

As described above, through step S1110 to step S1140, as the partial region 1232-1 of the channel layer 1232 corresponding to the GSL 1220 is formed of silicon, the remaining region 1232-2 of the channel layer 1232 corresponding to the plurality of word lines 1210 is formed of poly-silicon, and the remaining region 1205-2 of the substrate 1205 other than the upper surface 1205-1 is also formed of poly-silicon, the three-dimensional flash memory thus manufactured may improve the degree of integration by applying the COP structure and may prevent a leakage current at the GSL by improving a leakage current characteristic of the GSL TR (GSL TR referring to a region of the charge storage layer 1231, which is in contact with the GSL 1220) while guaranteeing a channel characteristic associated with the memory operation in the remaining region 1232-2 of the channel layer 1232 corresponding to the plurality of word lines 1210.

Below, in the X-Z cross-sectional view showing a three-dimensional flash memory, the three-dimensional flash memory will be illustrated and described under the assumption that components such as a bit line located on/over at least one string and a source line located under the at least one string are omitted for convenience of description. However, the three-dimensional flash memory to be described later is not limited thereto, and may be configured to include components necessary for a typical flash memory.

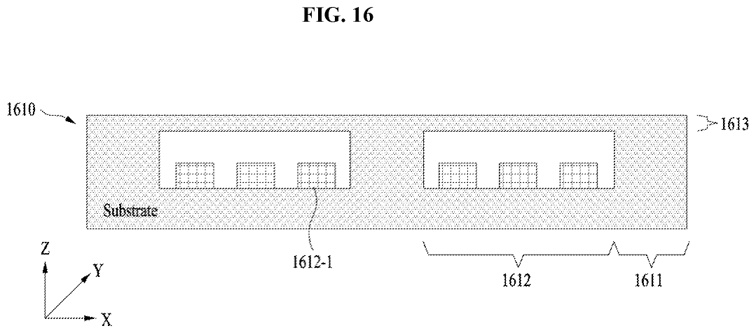

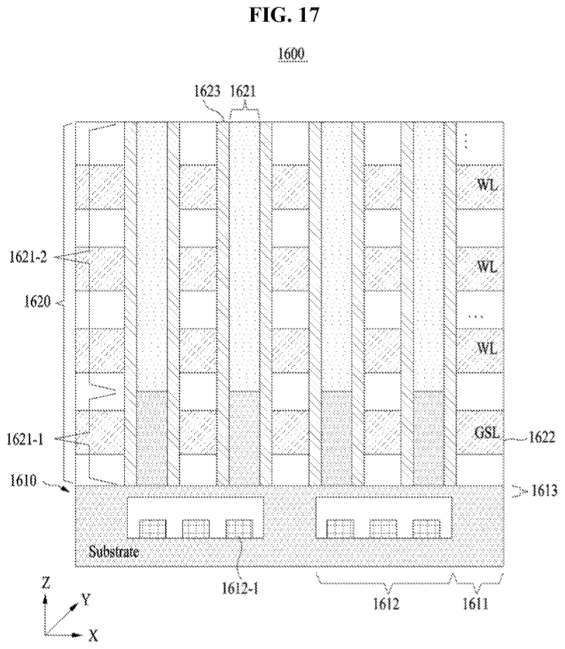

FIG. 16 is an X-Z cross-sectional view illustrating a substrate to which a COP structure used in a three-dimensional flash memory according to an embodiment is applied, and FIG. 17 is an X-Z cross-sectional view illustrating a three-dimensional flash memory in which a substrate illustrated in FIG. 16 is used.

Referring to FIGS. 16 and 17, a substrate 1610 according to an embodiment may include an epitaxial seed region 1611, a peripheral circuit region 1612, and an epitaxial growth layer 1613.

The epitaxial seed region 1611 may be used for the epitaxial growth for forming a portion 1621-1 corresponding to a ground selection line (GSL) 1622 among a channel layer 1621 included in a three-dimensional flash memory 1600 with single crystal silicon.

A peripheral circuit 1612-1 may be embedded in the peripheral circuit region 1612 by the COP structure.

The epitaxial growth layer 1613 may be disposed on an upper portion of the epitaxial seed region 1611 and the peripheral circuit region 1612 and may be formed by smoothing the single crystal silicon formed from the epitaxial seed region 1611 through the epitaxial growth. The epitaxial growth layer 1613 described above may allow at least one string including the channel layer 1621 and a charge storage layer 1623 to be formed over the entire upper region of the substrate 1610. Below, the charge storage layer 1623 that is a component trapping and storing charges or holes transferred from the channel layer 1621 or maintaining a state of charges (e.g., a polarization state of charges) may act as data storage in the three-dimensional flash memory 1600. For example, an oxide-nitride-oxide (ONO) layer or a ferroelectric layer may be used as the charge storage layer 1623.

In this case, under the epitaxial growth layer 1613, the epitaxial seed region 1611 and the peripheral circuit region 1612 form a pattern in which they are alternately repeated on the substrate 1610. For example, as illustrated in drawing, a pattern in which the epitaxial seed regions 1611 are disposed on opposite sides with the peripheral circuit region 1612 interposed therebetween may be repeated on the substrate 1610.

The three-dimensional flash memory 1600 according to an embodiment may include the substrate 1610 and a string region 1620 disposed on the substrate 1610, and the portion 1621-1 of the channel layer 1621 corresponding to the GSL 1622 may be formed of silicon through the epitaxial growth that is based on the substrate 1610 having the above structure. Herein, the remaining portion 1621-2 of the channel layer 1621 other than the portion 1621-1 corresponding to the GSL 1622 may be formed of poly-silicon (Poly-Si).

A method for manufacturing the three-dimensional flash memory 1600 using the substrate 1610 with the structure for the epitaxial growth will be described in detail below.

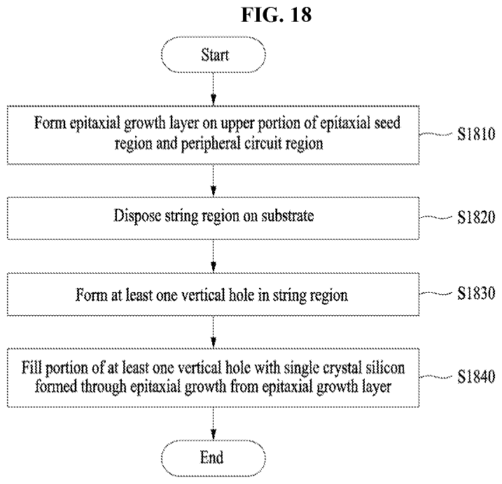

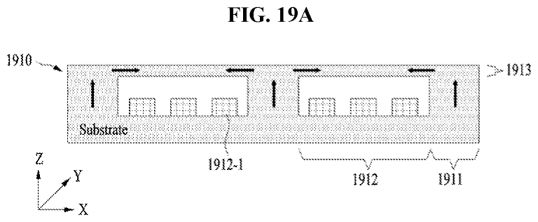

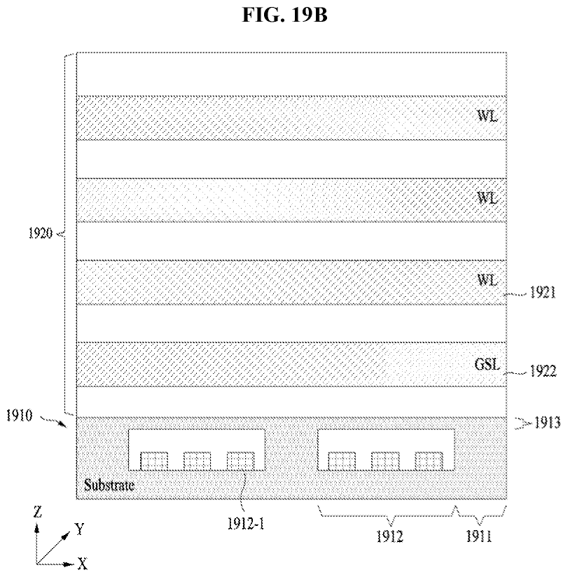

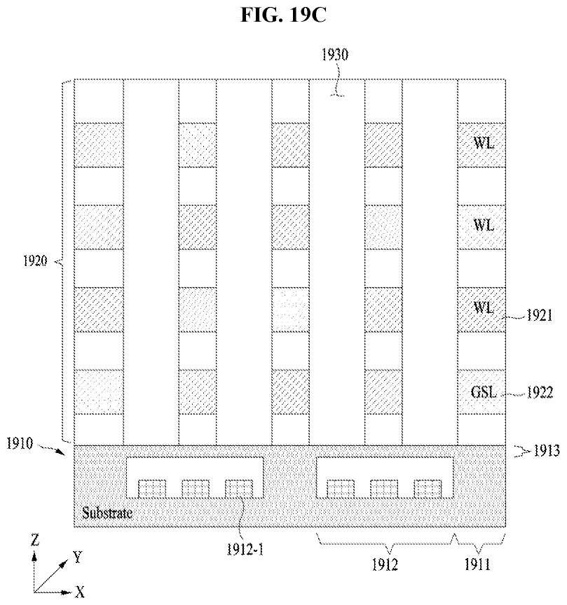

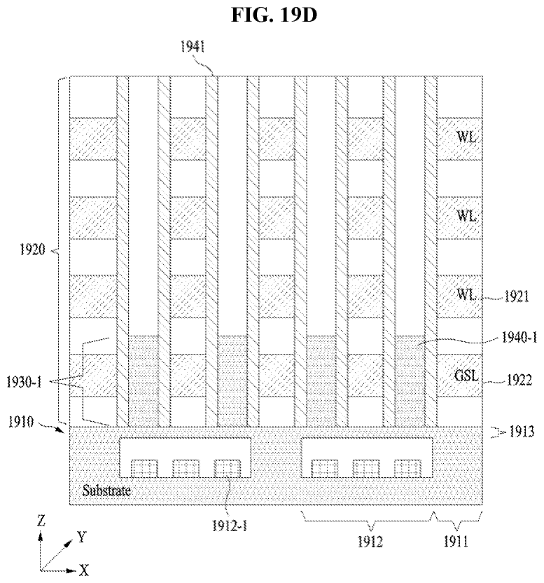

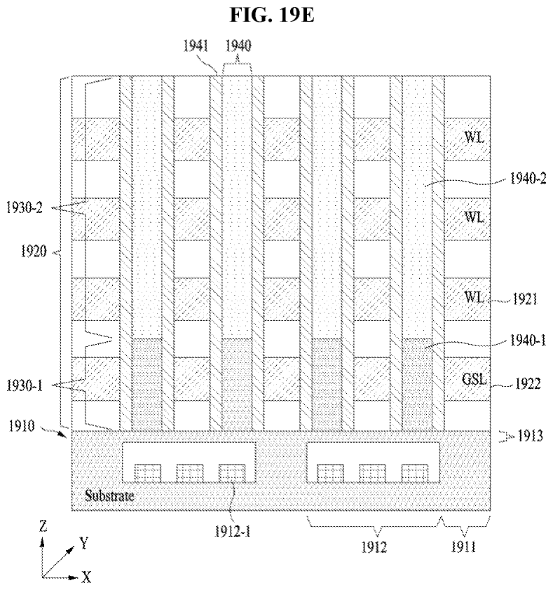

FIG. 18 is a flowchart illustrating a method for manufacturing a three-dimensional flash memory using a substrate to which a COP structure according to an embodiment is applied, and FIGS. 19A to 19E are X-Z cross-sectional views illustrating a three-dimensional flash memory for describing the manufacturing method illustrated in FIG. 18. Below, the manufacturing method is a process that is performed to manufacture the three-dimensional flash memory 1600 illustrated in FIG. 17, and the description will be given under the condition that the manufacturing method is performed by an automated and mechanized manufacturing system.

Referring to FIGS. 18 and 19A to 19E, in step S1810, the manufacturing system may generate an epitaxial growth layer 1913 on an upper portion of an epitaxial seed region 1911 and a peripheral circuit region 1912. For example, the manufacturing system may generate the epitaxial growth layer 1913 formed of single crystal silicon through the epitaxial growth from the epitaxial seed region 1911 and may perform a planarization process on the epitaxial growth layer 1913. As such, a substrate 1910 may include the epitaxial seed region 1911, the peripheral circuit region 1912, and the epitaxial growth layer 1913.

Herein, the epitaxial seed region 1911 may be a region that is used for the epitaxial growth for forming a portion 1940-1 of a channel layer 1940 (to be described later), which corresponds to a GSL 1922, and the peripheral circuit region 1912 may be a region in which a peripheral circuit 1912-1 is embedded by the COP structure.

In particular, the epitaxial seed region 1911 and the peripheral circuit region 1912 may form a pattern in which they are disposed alternately and repeatedly on the substrate 1910. For example, as illustrated in drawing, a pattern in which the epitaxial seed regions 1911 are disposed on opposite sides with the peripheral circuit region 1912 interposed therebetween may be repeated on the substrate 1910.

Next, in step S1820, the manufacturing system may dispose a string region 1920 on the substrate 1910 as illustrated in FIG. 19B.

In this case, a plurality of word lines 1921 that are extended and formed in a horizontal direction on the substrate 1910 and are sequentially stacked may be included in the string region 1920. Also, the GSL 1922 that is located under the plurality of word lines 1921 may be further included in the string region 1920.

Next, in step S1830, the manufacturing system may form at least one vertical hole 1930 in the string region 1920 as illustrated in FIG. 19C. In detail, in step S1930, the manufacturing system may form the at least one vertical hole 1930 in the string region 1920 with a depth by which the epitaxial growth layer 1913 is exposed.

Afterwards, in step S1840, the manufacturing system may fill single crystal silicon, which is formed through the epitaxial growth from the epitaxial growth layer 1913, at a portion of the at least one vertical hole 1930 as illustrated in FIG. 19D. In detail, in step S1840, the manufacturing system may extend and form the portion 1940-1 of the channel layer 1940 by filling the single crystal silicon within the at least one vertical hole 1930 up to a portion 1930-1 corresponding to the GSL 1922.

Although not illustrated by separate drawings and steps, between step S1830 and step S1840, the manufacturing system may deposit a charge storage layer 1941 over the entire region of an inner wall of the at least one vertical hole 1930. Because the inside of the charge storage layer 1941 is in an empty shape, in step S1840, the single crystal silicon may be filled at a portion of the inner hole of the charge storage layer 1941.

Also, although not illustrated by a separate step, after step S1840, the manufacturing system may extend and form the remaining portion 1940-2 of the channel layer 1940 by filling poly-silicon in the remaining portion 1930-2 of the at least one vertical hole 1930 as illustrated in FIG. 19E.

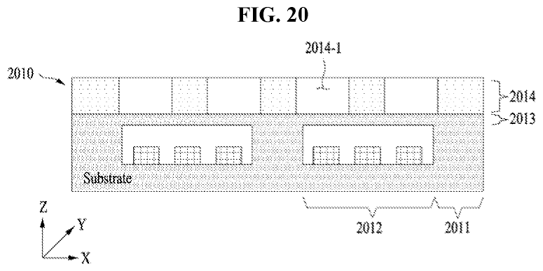

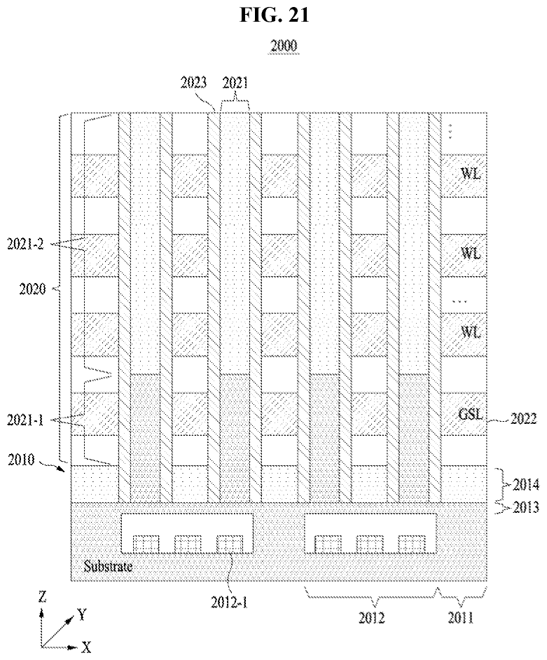

FIG. 20 is an X-Z cross-sectional view illustrating a substrate to which a COP structure used in a three-dimensional flash memory according to another embodiment is applied, and FIG. 21 is an X-Z cross-sectional view illustrating a three-dimensional flash memory in which a substrate illustrated in FIG. 20 is used.

Referring to FIGS. 20 and 21, a substrate 2010 according to another embodiment may include an epitaxial seed region 2011, a peripheral circuit region 2012, an epitaxial growth layer 2013, and a poly-silicon layer 2014.

The epitaxial seed region 2011 may be used for the epitaxial growth for forming a portion 2021-1 corresponding to a ground selection line (GSL) 2022 among a channel layer 2021 included in a three-dimensional flash memory 2000 with single crystal silicon.

A peripheral circuit 2012-1 may be embedded in the peripheral circuit region 2012 by the COP structure.

The epitaxial growth layer 2013 may be disposed on an upper portion of the epitaxial seed region 2011 and the peripheral circuit region 2012 and may be formed by smoothing the single crystal silicon formed from the epitaxial seed region 2011 through the epitaxial growth. The epitaxial growth layer 2013 described above may allow at least one string including the channel layer 2021 and a charge storage layer 2023 to be formed over the entire upper region of the substrate 2010.

In this case, under the epitaxial growth layer 2013, the epitaxial seed region 2011 and the peripheral circuit region 2012 form a pattern in which they are alternately repeated on the substrate 2010. For example, as illustrated in drawing, a pattern in which the epitaxial seed regions 2011 are disposed on opposite sides with the peripheral circuit region 2012 interposed therebetween may be repeated on the substrate 2010.

As the poly-silicon layer 2014 is disposed on the epitaxial growth layer 2013, the substrate 2010 may have a dual structure (e.g., a first layer composed of the epitaxial seed region 2011, the peripheral circuit region 2012, and the epitaxial growth layer 2013 and a second layer composed of the poly-silicon layer 2014).

Herein, at least one vertical hole 2014-1 that is filled with the single crystal silicon formed through the epitaxial growth from the epitaxial growth layer 2013 may be included in the poly-silicon layer 2014. The at least one vertical hole 2014-1 may be extended and formed to a string region 2020 disposed on the poly-silicon layer 2014 such that a channel layer 2021 is capable of being formed therein.

The three-dimensional flash memory 2000 according to another embodiment may include the substrate 2010 and the string region 2020 disposed on the substrate 2010, and the portion 2021-1 of the channel layer 2021 corresponding to the GSL 2022 may be formed of silicon through the epitaxial growth that is based on the substrate 2010 having the above structure. Herein, the remaining portion 2021-2 of the channel layer 2021 other than the portion 2021-1 corresponding to the GSL 2022 may be formed of poly-silicon (Poly-Si).

A method for manufacturing the three-dimensional flash memory 2000 using the substrate 2010 with the structure for the epitaxial growth will be described in detail below.

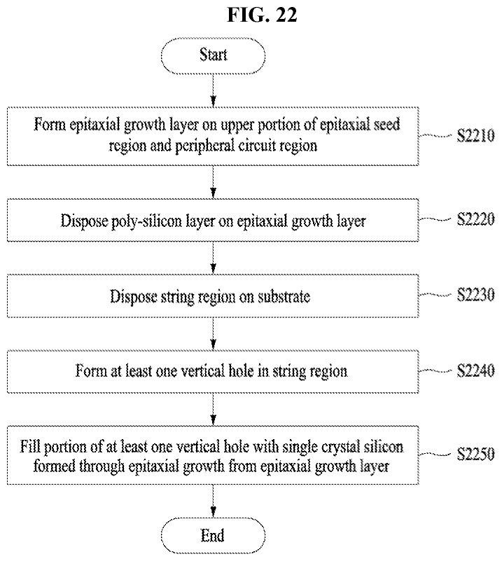

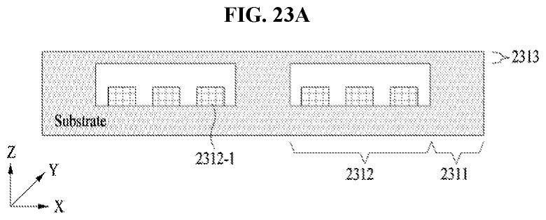

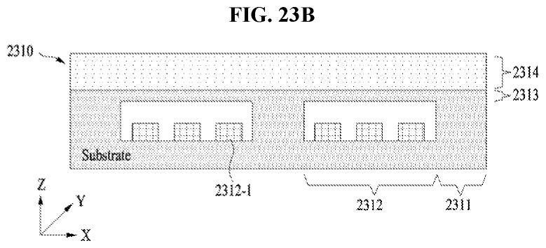

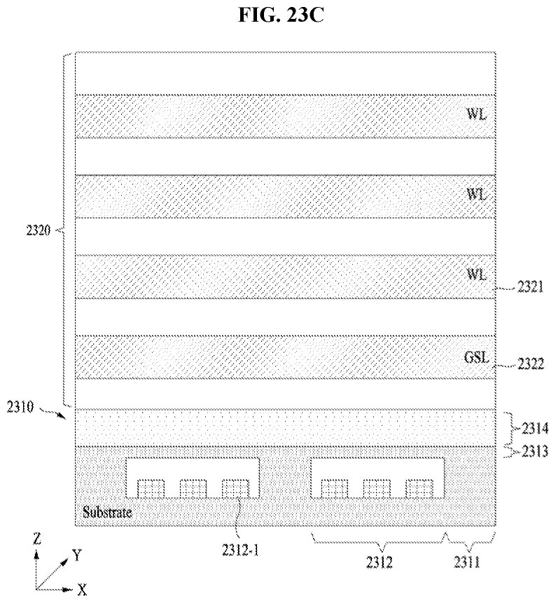

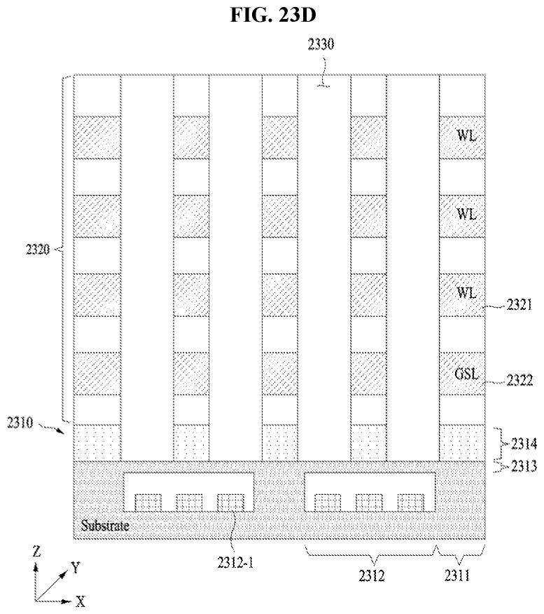

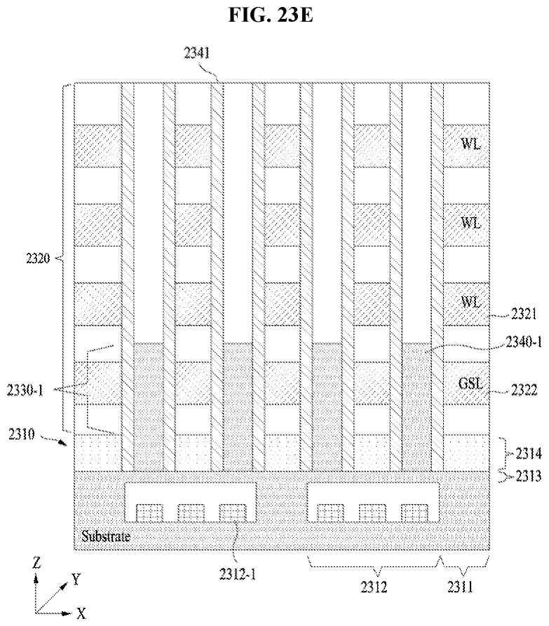

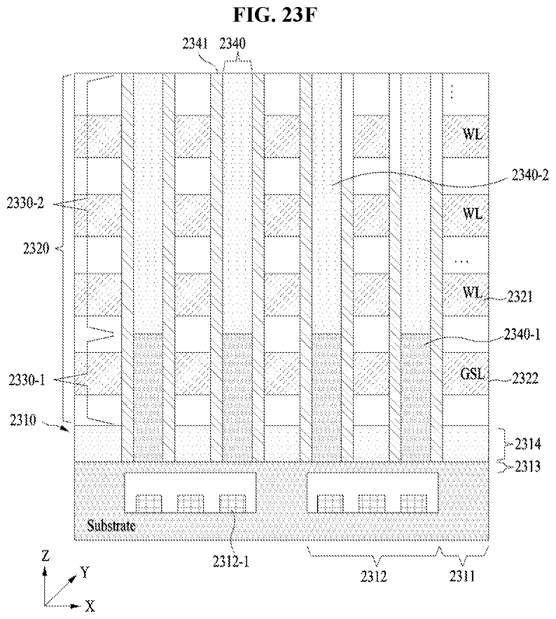

FIG. 22 is a flowchart illustrating a method for manufacturing a three-dimensional flash memory using a substrate to which a COP structure according to another embodiment is applied, and FIGS. 23A to 23F are X-Z cross-sectional views illustrating a three-dimensional flash memory for describing the manufacturing method illustrated in FIG. 22. Below, the manufacturing method is a process that is performed to manufacture a three-dimensional flash memory 2100 illustrated in FIG. 21, and the description will be given under the condition that the manufacturing method is performed by an automated and mechanized manufacturing system.

Referring to FIGS. 22 and 23A to 23F, in step S2210, the manufacturing system may generate an epitaxial growth layer 2313 on an upper portion of an epitaxial seed region 2311 and a peripheral circuit region 2312 as illustrated in FIG. 23A. For example, the manufacturing system may generate the epitaxial growth layer 2313 formed of single crystal silicon through the epitaxial growth from the epitaxial seed region 2311 and may perform a planarization process on the epitaxial growth layer 2313.

Herein, the epitaxial seed region 2311 may be a region that is used for the epitaxial growth for forming a portion 2340-1 of a channel layer 2340 (to be described later), which corresponds to a GSL 2322, and the peripheral circuit region 2312 may be a region in which a peripheral circuit 2312-1 is embedded by the COP structure.

In particular, the epitaxial seed region 2311 and the peripheral circuit region 2312 may form a pattern in which they are disposed alternately and repeatedly on a substrate 2310. For example, as illustrated in drawing, a pattern in which the epitaxial seed regions 2311 are disposed on opposite sides with the peripheral circuit region 2312 interposed therebetween may be repeated on the substrate 2310.

Next, in step S2220, the manufacturing system may dispose a poly-silicon layer 2314 on the epitaxial growth layer 2313 as illustrated in FIG. 23B.

As such, a substrate 2310 may include the epitaxial seed region 2311, the peripheral circuit region 2312, the epitaxial growth layer 2313, and the poly-silicon layer 2314.

Afterwards, in step S2230, the manufacturing system may dispose a string region 2320 on the substrate 2310 as illustrated in FIG. 23C.

In this case, a plurality of word lines 2321 that are extended and formed in a horizontal direction on the substrate 2310 and are sequentially stacked may be included in the string region 2320. Also, the GSL 2322 that is located under the plurality of word lines 2321 may be further included in the string region 2320.

Next, in step S2240, the manufacturing system may form at least one vertical hole 2330 in the string region 2320 as illustrated in FIG. 23D. In detail, in step S2240, the manufacturing system may form the at least one vertical hole 2330, which penetrates the string region 2320 and the poly-silicon layer 2314, with a depth by which the epitaxial growth layer 2313 is exposed.

Afterwards, in step S2250, the manufacturing system may fill single crystal silicon, which is formed through the epitaxial growth from the epitaxial growth layer 2313, at a portion of the at least one vertical hole 2330 as illustrated in FIG. 23E. In detail, in step S2250, the manufacturing system may extend and form the portion 2340-1 of the channel layer 2340 by filling the single crystal silicon within the at least one vertical hole 2330 up to a portion 2330-1 corresponding to the GSL 2322.

Although not illustrated by separate drawings and steps, between step S2240 and step S2250, the manufacturing system may deposit a charge storage layer 2341 over the entire region of an inner wall of the at least one vertical hole 2330. Because the inside of the charge storage layer 2341 is in an empty shape, in step S2250, the single crystal silicon may be filled at a portion of the inner hole of the charge storage layer 2341.

Also, although not illustrated by a separate step, after step S2250, the manufacturing system may extend and form the remaining portion 2340-2 of the channel layer 2340 by filling poly-silicon in the remaining portion 2330-2 of the at least one vertical hole 2330 as illustrated in FIG. 23F.

While embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Therefore, other implements, other embodiments, and equivalents to claims are within the scope of the following claims.

1. A three-dimensional flash memory comprising:
a string extended and formed in one direction on a substrate, wherein the string includes a channel layer extended and formed in the one direction and a charge storage layer extended and formed in the one direction to surround the channel layer;
at least one selection line vertically connected with an upper end or a lower end of the string; and
a plurality of word lines located over or under the at least one selection line and vertically connected with the string,
wherein the channel layer is formed of an oxide semiconductor material.

2. The three-dimensional flash memory claim 1, wherein the entire channel layer is formed of the oxide semiconductor material.

3. The three-dimensional flash memory claim 1, wherein a physical structure of the at least one selection line is determined based on a leakage current characteristic of the oxide semiconductor material forming the channel layer.

4. The three-dimensional flash memory claim 3, wherein the number or thickness of the at least one selection line is adjusted based on the leakage current characteristic of the oxide semiconductor material forming the channel layer.

5. The three-dimensional flash memory claim 4, wherein the at least one selection line is formed to be thinner than a thickness of each of the plurality of word lines.

6. A three-dimensional flash memory to which a COP structure is applied, comprising:
a plurality of word lines extended formed in a horizontal direction on a substrate and sequentially stacked;
a ground selection line (GSL) located under the plurality of word lines; and
at least one string extended and formed in a vertical direction on the substrate to penetrate the plurality of word lines and the GSL, wherein the at least one string includes a channel layer extended and formed in the vertical direction and a charge storage layer extended and formed in the vertical direction to surround the channel layer,
wherein a partial region of the channel layer, which corresponds to the GSL, is formed of silicon by using crystallized silicon of an upper surface of the substrate.

7. The three-dimensional flash memory claim 6, wherein the partial region of the channel layer, which corresponds to the GSL, is formed of the silicon through epitaxial growth that is based on the crystallized silicon of the upper surface of the substrate.

8. The three-dimensional flash memory claim 6, wherein the upper surface of the substrate is crystallized to the silicon as a laser annealing technique is applied to poly-silicon forming the substrate.

9. The three-dimensional flash memory claim 6, wherein a remaining region of the channel layer, which corresponds to the plurality of word lines, is formed of poly-silicon.

10. The three-dimensional flash memory claim 6, wherein a remaining region of the substrate other than the upper surface is formed of poly-silicon.

11. A substrate to which a COP structure used in a three-dimensional flash memory is applied, comprising:
an epitaxial seed region used for epitaxial growth for forming a portion of a channel layer included in the three-dimensional flash memory with single crystal silicon, wherein the portion of the channel layer corresponds to a ground selection line (GSL); and
a peripheral circuit region in which a peripheral circuit is embedded by the COP structure.

12. The substrate claim 11, wherein the epitaxial seed region and the peripheral circuit region form a pattern in which the epitaxial seed region and the peripheral circuit region are disposed alternately and repeatedly on the substrate.

13. The substrate claim 11, wherein an epitaxial growth layer in which single crystal silicon formed through the epitaxial growth from the epitaxial seed region is smoothed is disposed on an upper portion of the epitaxial seed region and the peripheral circuit region.

14. The substrate claim 13, further comprising:
a poly-silicon layer disposed on the epitaxial growth layer.

15. The substrate claim 14, wherein the poly-silicon layer includes:
at least one vertical hole filled with the single crystal silicon formed through the epitaxial growth from the epitaxial seed region.
